(19) United States
(12) Patent Application Publication
(10) Pub. No.: US 2026/0182357 A1
(43) Pub. Date: Jun. 25, 2026

(54) TOPOGRAPHIC LAYERED DIELECTRIC FOR SUBTRACTIVE INTERCONNECT

(71) Applicant: International Business Machines Corporation, Armonk, NY (US)

(72) Inventors: Kamal Rudra, Albany, NY (US); Ashim Dutta, Clifton Park, NY (US); Chih-Chao Yang, Glenmont, NY (US); Nilanka W Sirikkathuge, Guilderland, NY (US)

(21) Appl. No.: 18/991,594

(22) Filed: Dec. 22, 2024

(51) Int. Cl. H01L 23/532; H01L 21/768; H01L 23/522

(52) U.S. Cl. CPC H10W 20/47; H10W 20/075; H10W 20/42

(57) ABSTRACT

Interconnect structures having a topographic, layered dielectric are provided. In one aspect, an interconnect structure includes: a substrate; interconnects on the substrate; and a layered dielectric that includes layers of at least a first dielectric having a first dielectric constant κ₁ and a second dielectric having a second dielectric constant κ₂ disposed, in a repeating manner, on and between the interconnects, where κ₁>κ₂. The interconnect structure can also include more than two different dielectrics, such as a third dielectric having a third dielectric constant κ₃. A method of fabricating the present interconnect structures is also provided.

### BACKGROUND

The present invention relates generally to the electrical, electronic and computer arts and, more particularly, to interconnect structures having a topographic, layered dielectric.

Increased device scaling brings about some notable design challenges. For instance, as device dimensions become increasingly smaller, so does the spacing between adjacent structures. With conductors such as metal interconnects, a smaller spacing can boost capacitance which in turn can negatively impact performance parameters such as decreasing device speed.

Capacitance can be reduced by lowering the dielectric constant κ of the material between the conductors. In that regard, so called ‘ultralow-κ’ dielectric materials or even air gaps are sometimes employed between conductors to reduce capacitance. With an ultralow-κ dielectric material, the dielectric constant κ may be lowered by introducing porosity into the material. Doing so, however, reduces its mechanical strength.

### BRIEF SUMMARY

Principles of the invention provide interconnect structures having a topographic, layered dielectric. In one aspect, an interconnect structure is provided. The interconnect structure includes: a substrate; interconnects on the substrate; and a layered dielectric that includes layers of at least a first dielectric having a first dielectric constant κ₁ and a second dielectric having a second dielectric constant κ₂ disposed, in a repeating manner, on and between the interconnects, where κ₁ >κ₂.

In another aspect, another interconnect structure is provided. The interconnect structure includes: a substrate; interconnects on the substrate; and a layered dielectric that includes layers of at least a first dielectric having a first dielectric constant κ₁, a second dielectric having a second dielectric constant κ₂, and a third dielectric having a third dielectric constant κ₃ disposed, in repeating groups thereof, on and between the interconnects, where κ₁>κ₂>κ₃, and where the layered dielectric conforms to a topography of the interconnects.

In yet another aspect, a method of fabricating an interconnect structure is provided. The method includes: forming metal lines on a substrate; and forming a layered dielectric on and between the metal lines, where the layered dielectric includes layers of at least a first dielectric having a first dielectric constant κ₁ and a second dielectric having a second dielectric constant κ₂ deposited in a repeating manner on and between the metal lines, where κ₁>κ₂.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
A layered dielectric with a topography having layers of at least two (i.e., first and second) dielectrics of different dielectric constants κ_{X} between interconnects;
Whereby the first dielectric has a higher dielectric constant to enhance a mechanical strength of the layered dielectric;
Whereby the second dielectric has a lower dielectric constant to reduce capacitance between the interconnects; and
Whereby the interconnects can include metal lines and at least one top via, where the at least one top via directly contacts one of the metal lines.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1-3 are cross-sectional diagrams illustrating the fabrication of an exemplary interconnect structure, according to aspects of the invention;

FIG. 4 is a cross-sectional diagram, which follows from FIG. 1, illustrating the fabrication of another exemplary interconnect structure, according to aspects of the invention;

FIG. 5 is a cross-sectional diagram, which also follows from FIG. 1, illustrating the fabrication of yet another exemplary interconnect structure, according to aspects of the invention; and

FIGS. 6-9 are cross-sectional diagrams illustrating the fabrication of still yet another exemplary interconnect structure, according to aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

As their name implies, ‘interconnects’ in a semiconductor design serve to connect individual devices such as transistors through, e.g., a series of metal layers interspersed with an interlayer dielectric (ILD) material. For instance, structures like conductive vias and metal lines can be employed to connect a device to one or more other devices, to external connections, and the like, with the metal lines making lateral connections and the conductive vias making vertical connections amongst different metallization levels.

As highlighted above, when device dimensions are scaled, the capacitance between conductors such as interconnects can become a performance roadblock. While the capacitance between interconnects can be reduced using ultralow-κ dielectric materials, e.g., materials having a dielectric constant κ of less than 2.7, there can be a tradeoff in terms of mechanical strength. Namely, with ultralow-κ dielectric materials the dielectric constant κ may be lowered by introducing porosity into the material. This increased porosity, however, reduces its stiffness and strength lending the materials to failures such as cracking or other damage.

Advantageously, it has been found herein that employing the present layered dielectric design with dielectric materials of differing dielectric constants can provide the best of both worlds in terms of mechanical strength and lowered dielectric constant between interconnects. As will be described in detail below, this layered dielectric design employs conformal layers of the dielectric materials which are disposed on and between the interconnects. As such, the conformal layers take on a topography consisting of relative peaks and valleys, as opposed to a planar film having a primarily flat surface.

As will also be described in detail below, embodiments are contemplated herein where at least two different dielectric materials are used. They may be introduced in alternating layers. Embodiments are also contemplated herein where more than two different dielectric materials (e.g., three, four, etc. different dielectric materials) are incorporated in the layered dielectric. Further, the layered dielectric with topography can be employed throughout the interconnect structure or, alternatively, adjacent to and surrounding the interconnects themselves, with a planar layer of dielectric on top.

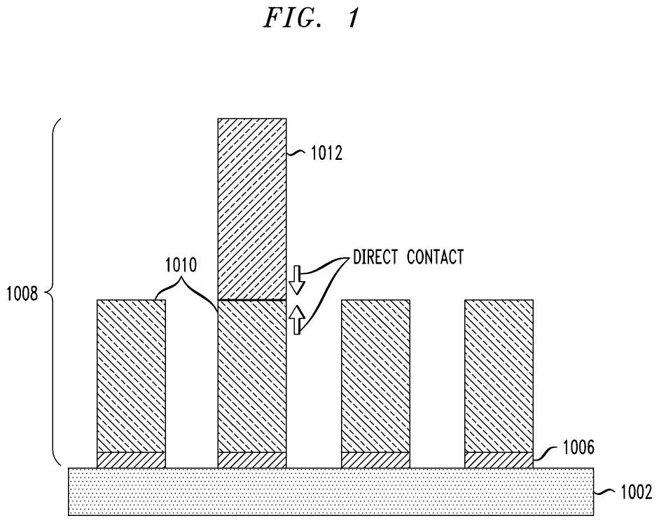

Given the above overview, an exemplary methodology for fabricating an interconnect structure in accordance with the present techniques is now described by way of reference to FIGS. 1-3, which are all cross-sectional views. Referring to FIG. 1, the process begins with the formation of interconnects 1008 on a substrate 1002 over diffusion barriers 1006.

According to an exemplary embodiment, the substrate 1002 is a bulk semiconductor wafer, such as a bulk silicon (Si), bulk germanium (Ge), bulk silicon germanium (SiGe) and/or bulk III-V semiconductor wafer. Alternatively, the substrate 1002 can be a semiconductor-on-insulator (SOI) wafer. A SOI wafer includes an SOI layer separated from an underlying substrate by a buried insulator. When the buried insulator is an oxide it is also referred to herein as a buried oxide or BOX. The SOI layer can include any suitable semiconductor material(s), such as Si, Ge, SiGe and/or a III-V semiconductor. Further, the substrate 1002 may already have pre-built structures (not shown) such as transistors, diodes, capacitors, resistors, interconnects, wiring, etc.

As its name implies, the diffusion barriers 1006 serve to prevent metals (see below) in the interconnects 1008 from diffusing into the substrate 1002. Suitable materials for the diffusion barriers 1006 include, but are not limited to, titanium (Ti), tantalum (Ta), ruthenium (Ru), tungsten (W), titanium nitride (TiN), tantalum nitride (TaN), ruthenium nitride (RuN), ruthenium tantalum (RuTa), ruthenium tantalum nitride (RuTaN) and/or tungsten nitride (WN), which can be deposited using a process such as chemical vapor deposition (CVD), atomic layer deposition (ALD) or physical vapor deposition (PVD).

In the example shown, the interconnects 1008 include metal lines 1010 and a top via 1012 directly contacting one of the metal lines 1010. In one exemplary embodiment, the metal lines 1010 and the top via 1012 are both formed using a subtractive etching process. With a subtractive etching process, blanket layers of materials are deposited onto the substrate 1002 (in this case a blanket layer of diffusion barrier material followed by a blanket layer of interconnect metal(s)), followed by a subtractive etch to pattern the materials into the diffusion barriers 1006 and the interconnects 1008 shown in FIG. 1. By comparison, an additive process, such as a damascene or dual-damascene technique, creates a structure by adding material to an existing pattern. It is notable, however, that the present techniques are more generally applicable to any type of interconnect structure, regardless of how the interconnects therein are made, be it by a subtractive etching process, an additive process, or some combination thereof. For instance, embodiments are also contemplated herein, and described below, where a combination of subtractive etching and a damascene process is used to form metal lines 1010′ and a top via 1012′, respectively.

Suitable metals for the metal lines 1010 and the top via 1012 include, but are not limited to, cobalt (Co), ruthenium (Ru), molybdenum (Mo), rhodium (Rh) and/or iridium (Ir), which can be deposited using a process or combination of processes including, but not limited to, CVD, ALD, PVD, sputtering, plating, evaporation, ion beam deposition, electron beam deposition, laser assisted deposition, chemical solution deposition, etc. Standard lithography and etching techniques can then be employed to pattern the metal into the interconnects 1008 and the diffusion barrier material into the diffusion barriers 1006.

With standard lithography and etching techniques, a lithographic stack (not shown), e.g., photoresist/anti-reflective coating/organic planarizing layer, is used to pattern a hardmask (not shown) with the footprint and location of, in this case, the interconnects 1008. Suitable hardmask materials include, but are not limited to, silicon nitride (SiN), silicon dioxide (SiO₂) (including low temperature oxides or LTOs deposited at a temperature of from about 400° C. to about 450° C.), titanium nitride (TiN) and/or silicon oxynitride (SiON). An etch is then performed to transfer the pattern from the hardmask to the underlying metal. Suitable etching processes include, but are not limited to, directional (anisotropic) etching processes such as reactive ion etching (RIE). Alternatively, the hardmask can be formed by other suitable techniques, including but not limited to, sidewall image transfer (SIT), self-aligned double patterning (SADP), self-aligned quadruple patterning (SAQP), and other self-aligned multiple patterning (SAMP).

Advantageously, with this process, the top via 1012 can be formed directly on, and in direct contact with, the respective one of the metal lines 1010. See FIG. 1. By contrast, conventional approaches which would involve the placement of intervening layers/liners between the top via 1012 and the metal lines 1010 can undesirably increase contact resistance. Further, the present techniques enable the use of different metals for the metal lines 1010 vis-á-vis the top via 1012, if so desired. Namely, embodiments are contemplated herein where the metal lines 1010 and the top via 1012 are formed from the same metal (or combination of metals) selected, e.g., from those suitable metals provided above. However, embodiments are also contemplated herein where the metal lines 1010 and the top via 1012 are formed from different metals (or different combinations of metals) selected, e.g., from those suitable metals provided above.

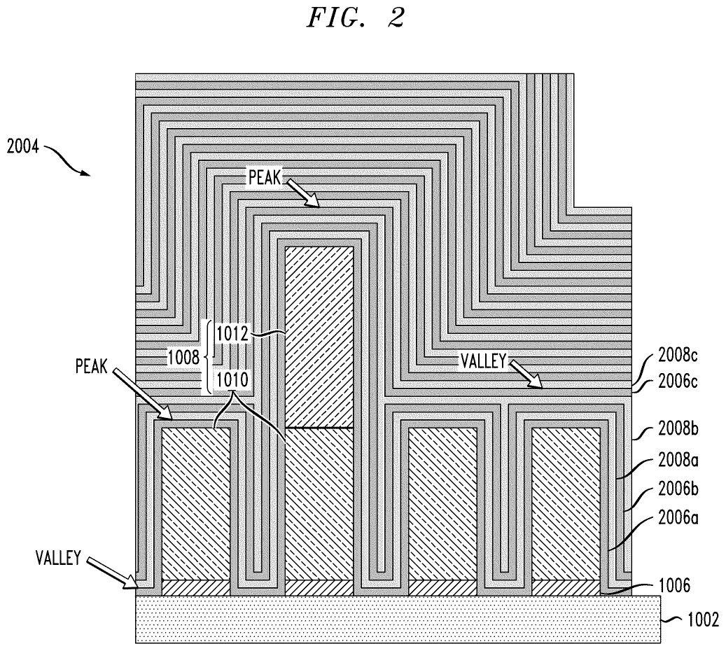

Referring to FIG. 2, a layered dielectric 2004 is then formed on and between the interconnects 1008. In general, the present layered dielectrics contain multiple dielectrics with different dielectric constants κ_{X} disposed in a repeating manner, e.g., alternating layers of two different dielectrics, repeating groups of layers containing more than two different dielectrics, etc. For instance, in this example, the layered dielectric 2004 is made up of alternating layers 2006a, b, c, etc. of a first dielectric and layers 2008a, b, c, etc of a second dielectric. This alternating pattern of layers, deposited one on top of another, repeats itself until the layered dielectric 2004 fully fills the space between the metal lines 1010 and the top via 1012, and fully covers the metal lines 1010 and the top via 1012 as shown in FIG. 2.

Further, the layers 2006a, b, c, etc. of the first dielectric and the layers 2008a, b, c, etc. of the second dielectric are each conformal such that the layered dielectric 2004 conforms to a topography of the interconnects 1008. For example, layer 2006a of the first dielectric has peaks over each of the metal lines 1010 and the top via 1012, and valleys at a base of each of the metal lines 1010. So does the layer 2008a of the second dielectric, and so on. As the space between the metal lines 1010 and the top via 1012 becomes filled, the peaks and valleys of subsequently deposited layers shift upward. For example, layer 2006c of the first dielectric has a peak over the top via 1012, and valleys over the metal lines 1010. So does the layer 2008c of the second dielectric, and so on.

As provided above, the first dielectric and the second dielectric employed have different dielectric constants κ_{X} from one another. Doing so provides the benefits of both mechanical strength and lower dielectric constant (for reduced capacitance) between the interconnects 1008. For instance, according to an exemplary embodiment, the first dielectric has a first dielectric constant κ₁ and the second dielectric has a second dielectric constant κ₂ (i.e., X=1 or 2), where κ₁>κ₂. Thus, the layers 2006a, b, c, etc. of the first dielectric provide the layered dielectric 2004 with enhanced mechanical strength (as compared, e.g., to use of a ULK-ILD material alone), while the layers 2008a, b, c, etc. of the second dielectric reduce the dielectric constant of the layered dielectric 2004 (and thus the capacitance) between the interconnects 1008 (as compared, e.g., to use of a low-κ material alone such as SiO₂). To use an illustrative, non-limiting example, in an embodiment, 3<κ₁<4 and κ₂<3. In that case, the first dielectric can be a material such as SiO₂ which has a dielectric constant of about 3.9, whereas the second dielectric can be a material such as porous organosilicate glass (pSiCOH) which has a dielectric constant of from about 1.8 to about 2.4 depending on composition and/or treatments.

A process such as ALD (preferred) or CVD can be used to conformally deposit the layers 2006a, b, c, etc. of the first dielectric and the layers 2008a, b, c, etc. of the second dielectric. Preferably, the deposition is carried out without exposing the layers 2006a, b, c, etc. of the first dielectric and the layers 2008a, b, c, etc. of the second dielectric to air (i.e., deposition is in the absence of air). Namely, oxygen can cause damage to dielectric materials such as pSiCOH. According to an exemplary embodiment, a thickness of each of the layers 2006a, b, c, etc. of the first dielectric and each of the layers 2008a, b, c, etc. of the second dielectric is from about 1 nanometer (nm) to about 5 nm. While the layers 2006a, b, c, etc. of the first dielectric and the layers 2008a, b, c, etc. of the second dielectric can all have a same thickness as one another, embodiments are also contemplated herein where the thickness of one or more of the layers 2006a, b, c, etc. of the first dielectric and/or one or more of the layers 2008a, b, c, etc. of the second dielectric varies relative to the others.

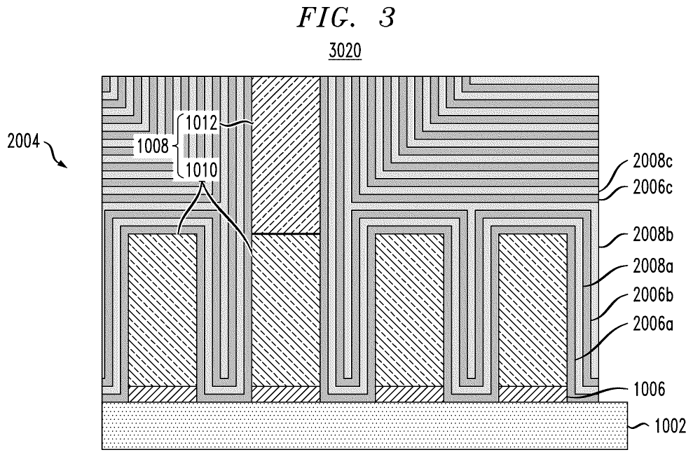

Referring to FIG. 3, the layered dielectric 2004 is then polished down to the top via 1012, using a process such as chemical-mechanical planarization (CMP). Doing so exposes a top surface of the top via 1012. See FIG. 3. Now present is an interconnect structure 3020 having the layered dielectric 2004 with the (alternating) layers 2006a, b, c, etc. of the first dielectric having the first dielectric constant κ₁ and the layers 2008a, b, c, etc. of the second dielectric having the second dielectric constant κ₂ disposed on and between the interconnects 1008, where κ₁>κ₂.

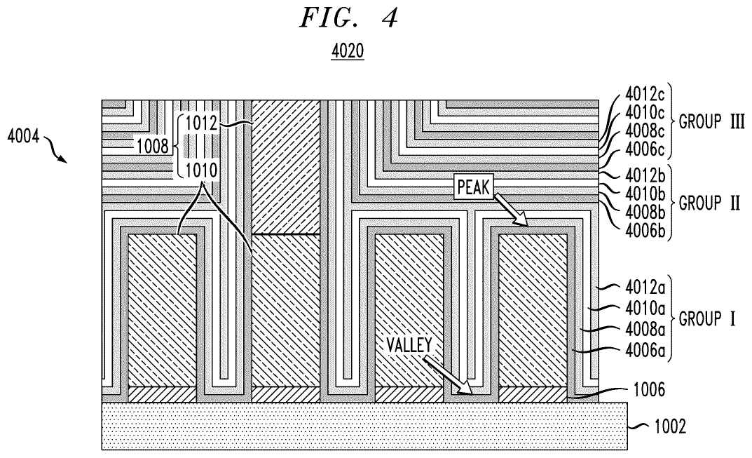

As highlighted above, embodiments are also contemplated herein where the present layered dielectric structure contains more than two dielectrics (e.g., three, four, etc. dielectrics) with different dielectric constants κ_{X}. This alternative embodiment is now described by way of reference to FIG. 4, a cross-sectional view. The process begins in the same general manner as in the previous example with the formation of the interconnects 1008 (i.e., the metal lines 1010 and the top via 1012 in direct contact therewith) on the substrate 1002 over the diffusion barriers 1006 using, for example, a subtractive etching process. Thus, what is depicted in FIG. 4 follows from the structure shown in FIG. 1, where like structures are numbered alike throughout the figures.

Referring to FIG. 4, a layered dielectric 4004 is then formed on and between the interconnects 1008. In this example, the layered dielectric 4004 is made up of repeating groups (i.e., Group I, Group II, Group III, etc.) of layers 4006a, b, c, etc., 4008a, b, c, etc., 4010a, b, c, etc. and 4012a, b, c, etc. of a first dielectric, a second dielectric, a third dielectric, and a fourth dielectric, respectively, deposited one on top of another. As shown in FIG. 4, these groups of layers repeat until the layered dielectric 4004 fully fills the space between the metal lines 1010 and the top via 1012, and fully covers the metal lines 1010 as shown in FIG. 4. For instance, layers 4006a, 4008a, 4010a and 4012a of the first dielectric, the second dielectric, the third dielectric, and the fourth dielectric, respectively, are deposited one on top of another forming Group I. That pattern is repeated by depositing layers 4006b, 4008b, 4010b and 4012b of the first dielectric, the second dielectric, the third dielectric, and the fourth dielectric, respectively, one on top of another forming Group II on the Group I, then depositing layers 4006c, 4008c, 4010c and 4012c of the first dielectric, the second dielectric, the third dielectric, and the fourth dielectric, respectively, one on top of another forming Group III on the Group II, and so on.

It is notable that the depiction of repeating groups containing four different dielectrics is merely an illustrative, non-limiting example. More generally, in accordance with the present techniques, each group (e.g., Group I, Group II, Group III, each) contains at least two dielectrics with different dielectric constants κ_{X} (e.g., κ₁ and κ₂ (X=1 or 2), where κ₁>κ₂), as in the previous example. However, by contrast with the previous example, embodiments are also contemplated herein where a third dielectric with a different dielectric constant κ₃ (where κ₁>κ₂>κ₃) is further included in each group, and those where a fourth dielectric with a different dielectric constant κ₄ (where κ₁>κ₂>κ₃>κ₄) is also included in each group, and so on.

Further, the layers 4006a, b, c, etc., 4008a, b, c, etc., 4010a, b, c, etc. and 4012a, b, c, etc. of the first dielectric, the second dielectric, the third dielectric, and the fourth dielectric, respectively, are each conformal such that the layered dielectric 4004 conforms to a topography of the interconnects 1008. For example, layer 4006a of the first dielectric has peaks over each of the metal lines 1010, and valleys at a base of each of the metal lines 1010. So do the layers 4008a, 4010a and 4012a of the second dielectric, the third dielectric, and the fourth dielectric, respectively, and so on.

As provided above, the first dielectric, the second dielectric, the third dielectric, the fourth dielectric, etc. have different dielectric constants κ_{X} from one another. Doing so provides the benefits of both mechanical strength and lower dielectric constant (for reduced capacitance) between the interconnects 1008. For instance, according to an exemplary embodiment, the first dielectric, the second dielectric, the third dielectric and the fourth dielectric, have a first dielectric constant κ₁, a second dielectric constant κ₂, a third dielectric constant κ₃ and a fourth dielectric constant κ₄, respectively, where κ₁>κ₂>κ₃>κ₄.

Thus, in the same manner as above, by staggering the dielectric constants of the first-fourth dielectrics, the layered dielectric 4004 as a whole has both the properties of enhanced mechanical strength (as compared, e.g., to use of a ULK-ILD material alone) while at the same time a reduced dielectric constant (and thus the capacitance) between the interconnects 1008 (as compared, e.g., to use of a low-κ material alone such as SiO₂). To use an illustrative, non-limiting example, in an embodiment, 2<κ_{X}<4 where X=1, 2, 3 or 4. In other words, the first dielectric constant κ₁ of the first dielectric is 2<κ₁<4, the second dielectric constant κ₂ of the second dielectric is 2<κ₂<4, the third dielectric constant κ₃ of the third dielectric is 2<κ₃<4, and the fourth dielectric constant κ₄ of the fourth dielectric is 2<κ₄<4, subject to the condition above that κ₁>κ₂>κ₃>κ₄.

A process such as ALD or CVD can be used to conformally deposit the layers 4006a, b, c, etc., 4008a, b, c, etc., 4010a, b, c, etc. and 4012a, b, c, etc. of the first dielectric, the second dielectric, the third dielectric, and the fourth dielectric, respectively. Preferably, the deposition is carried out without exposing the layers 4006a, b, c, etc., 4008a, b, c, etc., 4010a, b, c, etc. and 4012a, b, c, etc. to air (i.e., deposition in the absence of air). Namely, as highlighted above, oxygen can cause damage to dielectric materials such as pSiCOH. According to an exemplary embodiment, a thickness of each of the layers 4006a, b, c, etc., 4008a, b, c, etc., 4010a, b, c, etc. and 4012a, b, c, etc. of the first dielectric, the second dielectric, the third dielectric, and the fourth dielectric, respectively, is from about 1 nm to about 5 nm. While the layers 4006a, b, c, etc., 4008a, b, c, etc., 4010a, b, c, etc. and 4012a, b, c, etc. of the first dielectric, the second dielectric, the third dielectric, and the fourth dielectric, respectively can all have a same thickness as one another, embodiments are also contemplated herein where the thickness of one or more of the layers 4006a, b, c, etc., 4008a, b, c, etc., 4010a, b, c, etc. and/or 4012a, b, c, etc. of the first dielectric, the second dielectric, the third dielectric, and/or the fourth dielectric, respectively, varies relative to the others.

Following deposition, the layered dielectric 4004 is polished down to the top via 1012, using a process such as CMP. Doing so exposes a top surface of the top via 1012. See FIG. 4. Now present is an interconnect structure 4020 having the layered dielectric 4004 with the layers 4006a, b, c, etc. of the first dielectric having the first dielectric constant κ₁, the layers 4008a, b, c, etc. of the second dielectric having the second dielectric constant κ₂, the layers 4010a, b, c, etc. of the third dielectric having the third dielectric constant κ₃, and the layers 4012a, b, c, etc. of the fourth dielectric having the fourth dielectric constant κ₄, in repeating groups thereof, on and between the interconnects 1008, where κ₁>κ₂>κ₃>κ₄.

As highlighted above, embodiments are further contemplated herein where the present layered dielectric structure is employed adjacent to and surrounding the interconnects themselves, with a planar layer of dielectric on top. By ‘planar’ it is meant that this top layer of dielectric is flat and non-conformal meaning that it does not conform to the topography of the underlying interconnects.

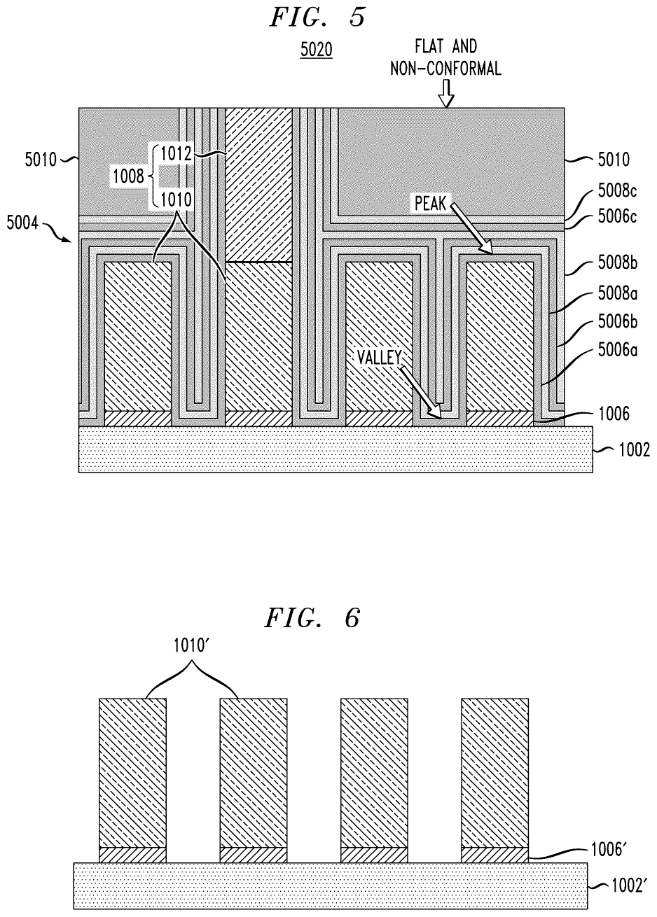

This alternative embodiment is now described by way of reference to FIG. 5, which is a cross-sectional view. The process begins in the same general manner as in the previous examples with the formation of the interconnects 1008 (i.e., the metal lines 1010 and the top via 1012 in direct contact therewith) on the substrate 1002 over the diffusion barriers 1006 using, for example, a subtractive etching process. Thus, what is depicted in FIG. 5 follows from the structure shown in FIG. 1, where like structures are numbered alike throughout the figures.

Referring to FIG. 5, a layered dielectric 5004 is then formed on and between the interconnects 1008. In this example, the layered dielectric 5004 is made up of alternating layers 5006a, b, c, etc. and 5008a, b, c, etc. of a first dielectric and a second dielectric, respectively. This alternating pattern of layers, deposited one on top of another, repeats itself until the layered dielectric 5004 fully fills the space between the metal lines 1010 and the top via 1012. However, by comparison with the earlier example from FIG. 3 (where the layered dielectric 2004 fully covered the metal lines 1010), here deposition of the conformal layers 5006a, b, c, etc. and 5008a, b, c, etc. of the first and second dielectrics is carried out until the layered dielectric 5004 fully fills the space between the metal lines 1010. After which, a single planar layer 5010 of the first dielectric is deposited on the conformal layers 5006a, b, c, etc. and 5008a, b, c, etc. over the metal lines 1010 and alongside the top via 1012. As provided above, the first dielectric has the first dielectric constant κ₁, where κ₁>κ₂ (e.g., 3<κ₁<4 and κ₂<3), and may be deposited using a process such as ALD or CVD (preferably without exposure to air).

In the same manner as above, the layers 5006a, b, c, etc. of the first dielectric and the layers 5008a, b, c, etc. of the second dielectric are each conformal such that the layered dielectric 5004 conforms to a topography of the interconnects 1008. For example, layer 5006a of the first dielectric has peaks over each of the metal lines 1010, and valleys at a base of each of the metal lines 1010. So does the layer 5008a of the second dielectric, and so on.

However, with this alternative configuration, the conformal alternating layers 5006a, b, c, etc. and 5008a, b, c, etc. of the first dielectric and the second dielectric are present adjacent to and surrounding the metal lines 1010 and the top via 1012 themselves, but do not fully bury the metal lines 1010 as in the previous examples. Instead, this is accomplished using the single planar layer 5010 of the first dielectric which, as shown in FIG. 5, is flat and non-conformal, i.e., it does not conform to the topography of the underlying interconnects 1008.

In the same manner as above, the first dielectric and the second dielectric employed have a different dielectric constant κ from one another in order to leverage the benefits of both mechanical strength and lower dielectric constant (for reduced capacitance) between the interconnects 1008. For instance, according to an exemplary embodiment, the first dielectric has a first dielectric constant κ₁ and the second dielectric has a second dielectric constant κ₂, where κ₁>κ₂. To use an illustrative, non-limiting example, in one exemplary embodiment, 3<κ₁<4 and κ₂<3.

A process such as ALD or CVD can be used to conformally deposit the layers 5006a, b, c, etc. of the first dielectric and the layers 5008a, b, c, etc. of the second dielectric. Preferably, the deposition is carried out without exposing the layers 5006a, b, c, etc. of the first dielectric and the layers 5008a, b, c, etc. of the second dielectric to air (i.e., deposition is in the absence of air). As provided above, oxygen can cause damage to dielectric materials such as pSiCOH. According to an exemplary embodiment, a thickness of each of the layers 5006a, b, c, etc. of the first dielectric and each of the layers 5008a, b, c, etc. of the second dielectric is from about 1 nm to about 5 nm. While the layers 5006a, b, c, etc. of the first dielectric and the layers 5008a, b, c, etc. of the second dielectric can all have a same thickness as one another, embodiments are also contemplated herein where the thickness of one or more of the layers 5006a, b, c, etc. of the first dielectric and/or one or more of the layers 5008a, b, c, etc. of the second dielectric varies relative to the others.

Following deposition of the single planar layer 5010 of the first dielectric, the layered dielectric 5004 is polished down to the top via 1012, using a process such as CMP. Doing so exposes a top surface of the top via 1012. See FIG. 5. Now present is an interconnect structure 5020 having the layered dielectric 5004 where layers 5006a, b, c, etc. of the first dielectric and the layers 5008a, b, c, etc. of the second dielectric are present adjacent to and surrounding the metal lines 1010 and the top via 1012, and the single planar layer 5010 of the first dielectric is disposed over the metal lines 1010 alongside the top via 1012.

In the previous examples, the metal lines 1010 and the top via 1012 (i.e., the interconnects 1008) are both formed using a subtractive etching process. However, other approaches may also be employed. For instance, embodiments are also contemplated herein where the same subtractive etching process as above is used for forming metal lines 1010′, while a damascene process is used to form a top via 1012′.

This alternative embodiment is now described by way of reference to FIGS. 6-9, which are all cross-sectional views. Referring to FIG. 6, the process begins with the formation of metal lines 1010′ on a substrate 1002′ over diffusion barriers 1006′. The metal lines 1010′ along with the top via 1012′ (to be formed below) together form interconnects 1008′ of the present structure.

In the same manner as above, the substrate 1002′ can be a bulk semiconductor wafer, such as a bulk Si, bulk Ge, bulk SiGe and/or bulk III-V semiconductor wafer. Alternatively, the substrate 1002′ can be an SOI wafer. Further, the substrate 1002′ may already have pre-built structures (not shown) such as transistors, diodes, capacitors, resistors, interconnects, wiring, etc. Suitable materials for the diffusion barriers 1006′ include, but are not limited to, Ti, Ta, Ru, W, TiN, TaN, RuN, RuTa, RuTaN and/or WN, which can be deposited using a process such as CVD, ALD or PVD.

According to an exemplary embodiment, the metal lines 1010′ are formed using a subtractive etching process (see above), whereby blanket layers of materials are deposited onto the substrate 1002′ (in this case a blanket layer of diffusion barrier material followed by a blanket layer of interconnect metal(s)), followed by a subtractive etch to pattern the materials into the diffusion barriers 1006′ and the metal lines 1010′ shown in FIG. 6. Suitable metals for the metal lines 1010′ include, but are not limited to, Co, Ru, Mo, Rh and/or Ir, which can be deposited using a process or combination of processes including, but not limited to, CVD, ALD, PVD, sputtering, plating, evaporation, ion beam deposition, electron beam deposition, laser assisted deposition, chemical solution deposition, etc. Standard lithography and etching techniques (see above) can then be employed to pattern the metal into the metal lines 1010′ and the diffusion barrier material into the diffusion barriers 1006′.

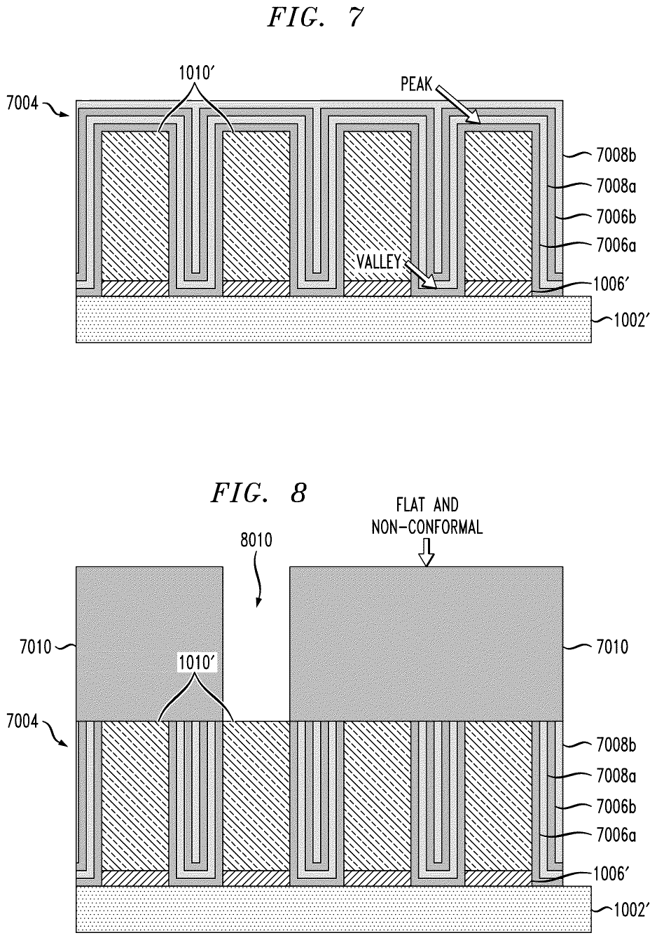

Referring to FIG. 7, a layered dielectric 7004 is then formed on and between the metal lines 1010′. In this example, the layered dielectric 7004 is made up of alternating layers 7006a, b, etc. and 7008a, b, etc. of a first dielectric and a second dielectric, respectively. This alternating pattern of layers, deposited one on top of another, repeats itself until the layered dielectric 7004 fully fills the space between the metal lines 1010′, and fully covers the metal lines 1010′ as shown in FIG. 7.

Further, the layers 7006a, b, etc. of the first dielectric and the layers 7008a, b, etc. of the second dielectric are each conformal such that the layered dielectric 7004 conforms to a topography of the metal lines 1010′. For example, layer 7006a of the first dielectric has peaks over each of the metal lines 1010′, and valleys at a base of each of the metal lines 1010′. So does the layer 7008a of the second dielectric, and so on.

In the same manner as above, the first dielectric and the second dielectric employed have different dielectric constants κ_{X} from one another. Doing so provides the benefits of both mechanical strength and lower dielectric constant (for reduced capacitance) between the metal lines 1010′. For instance, according to an exemplary embodiment, the first dielectric has a first dielectric constant κ₁ and the second dielectric has a second dielectric constant κ₂, where κ₁>κ₂. Thus, the layers 7006a, b, etc. of the first dielectric (κ₁) provide the layered dielectric 7004 with enhanced mechanical strength (as compared, e.g., to use of a ULK-ILD material alone), while the layers 7008a, b, etc. of the second dielectric (κ₂) reduce the dielectric constant of the layered dielectric 7004 (and thus the capacitance) between the metal lines 1010′ (as compared, e.g., to use of a low-κ material alone such as SiO₂). To use an illustrative, non-limiting example, in one exemplary embodiment, 3<κ₁<4 and κ₂<3.

A process such as ALD or CVD can be used to conformally deposit the layers 7006a, b, etc. of the first dielectric and the layers 7008a, b, etc. of the second dielectric. Preferably, the deposition is carried out without exposing the layers 7006a, b, etc. of the first dielectric and the layers 7008a, b, etc. of the second dielectric to air (i.e., deposition is in the absence of air). According to an exemplary embodiment, a thickness of each of the layers 7006a, b, etc. of the first dielectric and each of the layers 7008 a, b, etc. of the second dielectric is from about 1 nm to about 5 nm. While the layers 7006a, b, etc. of the first dielectric and the layers 7008a, b, etc. of the second dielectric can all have a same thickness as one another, embodiments are also contemplated herein where the thickness of one or more of the layers 7006a, b, etc. of the first dielectric and/or one or more of the layers 7008a, b, etc. of the second dielectric varies relative to the others.

Following deposition, a process such as CMP is used to polish the layers 7006a, b, etc. of the first dielectric and the layers 7008a, b, etc. of the second dielectric down to the metal lines 1010′. Referring to FIG. 8, a single planar layer 7010 of the first dielectric is then deposited on the layers 7006a, b, etc. /layers 7008a, b, etc. of the first/second dielectrics and the metal lines 1010′. As provided above, the first dielectric has the first dielectric constant κ₁, where κ₁>κ₂ (e.g., 3<κ₁<4 and κ₂<3), and may be deposited using a process such as ALD or CVD (preferably without exposure to air). As shown in FIG. 8, the single planar layer 7010 of the first dielectric is flat and non-conformal, i.e., it does not conform to the topography of the underlying metal lines 1010′.

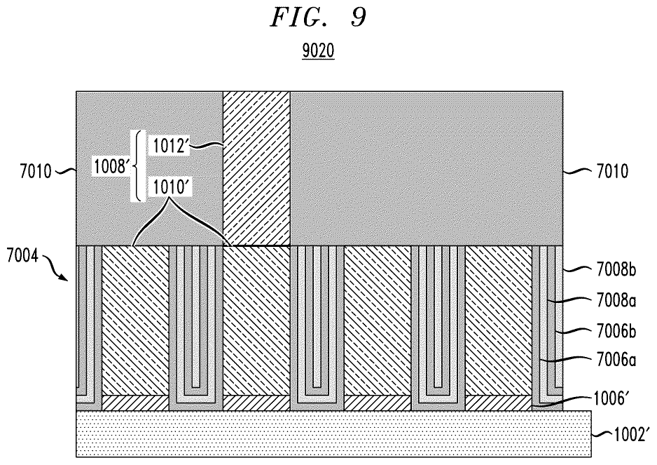

Standard lithography and etching techniques (see above) are next used to pattern a via 8010 in the single planar layer 7010 of the first dielectric over one of the metal lines 1010′. Doing so begins the damascene process used to form the top via 1012′. Namely, referring to FIG. 9, a metal (or combination of metals) is then deposited into and filling the via 8010, thereby forming the top via 1012′ which directly contacts the corresponding one of the metal lines 1010′. Any metal overburden can be removed using a process such as CMP. Suitable metals for the top via 1012′ include, but are not limited to, Co, Ru, Mo, Rh and/or Ir, which can be deposited using a process or combination of processes including, but not limited to, CVD, ALD, PVD, sputtering, plating, evaporation, ion beam deposition, electron beam deposition, laser assisted deposition, chemical solution deposition, etc. Embodiments are contemplated herein where the metal lines 1010′ and the top via 1012′ are formed from the same metal (or combination of metals) selected, e.g., from those suitable metals provided above. However, embodiments are also contemplated herein where the metal lines 1010′ and the top via 1012′ are formed from different metals (or different combinations of metals) selected, e.g., from those suitable metals provided above. Now present is an interconnect structure 9020 having the layered dielectric 7004 where layers 7006a, b, etc. of the first dielectric and the layers 7008a, b, etc. of the second dielectric are present adjacent to and surrounding the metal lines 1010′, and the single planar layer 7010 of the first dielectric is disposed over the metal lines 1010′ alongside the top via 1012′.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, such as chemical oxide removal (COR) etching, and reactive ion etching, respectively, which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, an exemplary interconnect structure (e.g., interconnect structure 3020, interconnect structure 4020, interconnect structure 5020, interconnect structure 9020, etc.) includes: a substrate (e.g., substrate 1002, substrate 1002′, etc.); interconnects (e.g., interconnects 1008, interconnects 1008′, etc.) on the substrate; and a layered dielectric (e.g., layered dielectric 2004, layered dielectric 4004, layered dielectric 5004, layered dielectric 7004, etc.) which includes layers of at least a first dielectric (e.g., layers 2006a, b, c, etc. of a first dielectric, layers 4006a, b, c, etc. of a first dielectric, layers 5006a, b, c, etc. of a first dielectric, layers 7006a, b, etc. of a first dielectric, etc.) having a first dielectric constant κ₁ and a second dielectric (e.g., layers 2008a, b, c, etc. of a second dielectric, layers 4008a, b, c, etc. of a second dielectric, layers 5008a, b, c, etc. of a second dielectric, layers 7008a, b, etc. of a second dielectric, etc.) having a second dielectric constant κ₂ disposed, in a repeating manner, on and between the interconnects, where κ₁>κ₂.

In accordance with other aspects of the present techniques, another exemplary interconnect structure (e.g., interconnect structure 4020) includes: a substrate (e.g., substrate 1002); interconnects (e.g., interconnects 1008) on the substrate; and a layered dielectric (e.g., layered dielectric 4004) which includes layers of at least a first dielectric (e.g., layers 4006a, b, c, etc. of a first dielectric) having a first dielectric constant κ₁, a second dielectric (e.g., layers 4008a, b, c, etc. of a second dielectric) having a second dielectric constant κ₂, and a third dielectric (e.g., layers 4010a, b, c, etc. of a third dielectric) having a third dielectric constant κ₃ disposed, in repeating groups thereof (e.g., Group I, Group II, Group III, etc.), on and between the interconnects, where κ₁ >κ₂>κ₃, and where the layered dielectric conforms to a topography of the interconnects.

In accordance with further aspects of the present techniques, a method of fabricating an interconnect structure (e.g., interconnect structure 3020, interconnect structure 4020, interconnect structure 5020, interconnect structure 9020, etc.) includes: forming metal lines (e.g., metal lines 1010, metal lines 1010′, etc.) on a substrate (e.g., substrate 1002, substrate 1002′, etc.); and forming a layered dielectric (e.g., layered dielectric 2004, layered dielectric 4004, layered dielectric 5004, layered dielectric 7004, etc.) on and between the metal lines, where the layered dielectric includes layers of at least a first dielectric (e.g., layers 2006a, b, c, etc. of a first dielectric, layers 4006a, b, c, etc. of a first dielectric, layers 5006a, b, c, etc. of a first dielectric, layers 7006a, b, etc. of a first dielectric, etc.) having a first dielectric constant κ₁ and a second dielectric (e.g., layers 2008a, b, c, etc. of a second dielectric, layers 4008a, b, c, etc. of a second dielectric, layers 5008a, b, c, etc. of a second dielectric, layers 7008a, b, etc. of a second dielectric, etc.) having a second dielectric constant κ₂ deposited in a repeating manner on and between the metal lines, where κ₁>κ₂.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of the disclosed topographic layered dielectric scheme.

An integrated circuit in accordance with aspects of the present inventions can be employed in essentially any application and/or electronic system where one or more aspects of the disclosed topographic layered dielectric scheme would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. An interconnect structure, comprising:
a substrate;
interconnects on the substrate; and
a layered dielectric comprising layers of at least a first dielectric having a first dielectric constant κ₁ and a second dielectric having a second dielectric constant κ₂ disposed, in a repeating manner, on and between the interconnects, wherein κ₁>κ₂.

2. The interconnect structure of claim 1, wherein the repeating manner comprises alternating layers of the first dielectric and the second dielectric disposed on and between the interconnects.

3. The interconnect structure of claim 1, wherein the layered dielectric conforms to a topography of the interconnects.

4. The interconnect structure of claim 1, wherein 3<κ₁<4, and wherein κ₂<3.

5. The interconnect structure of claim 1, wherein the interconnects comprise metal lines.

6. The interconnect structure of claim 5, wherein the interconnects further comprise at least one top via, and wherein the at least one top via directly contacts one of the metal lines.

7. The interconnect structure of claim 6, wherein the metal lines and the at least one top via both comprise a same metal.

8. The interconnect structure of claim 6, wherein the metal lines and the at least one top via comprise different metals.

9. The interconnect structure of claim 6, wherein the layers of the first dielectric and the second dielectric disposed in the repeating manner are present adjacent to and surrounding the metal lines and the at least one top via, and wherein the structure further comprises:
a single planar layer of the first dielectric disposed over the metal lines and alongside the at least one top via.

10. The interconnect structure of claim 1, wherein a thickness of each of the layers of the first dielectric and each of the layers of the second dielectric is from about 1 nanometer to about 5 nanometers.

11. An interconnect structure, comprising:
a substrate;
interconnects on the substrate; and
a layered dielectric comprising layers of at least a first dielectric having a first dielectric constant κ₁, a second dielectric having a second dielectric constant κ₂, and a third dielectric having a third dielectric constant κ₃ disposed, in repeating groups thereof, on and between the interconnects, wherein κ₁>κ₂>κ₃, and wherein the layered dielectric conforms to a topography of the interconnects.

12. The interconnect structure of claim 11, wherein the layers of the layered dielectric further comprise:
a fourth dielectric having a fourth dielectric constant κ₄, wherein κ₁>κ₂>κ₃>κ₄.

13. The interconnect structure of claim 12, wherein 2<κ_{X}<4, with X=1, 2, 3 or 4.

14. The interconnect structure of claim 13, wherein the interconnects comprise metal lines.

15. The interconnect structure of claim 14, wherein the interconnects further comprise at least one top via, and wherein the at least one top via directly contacts one of the metal lines.

16. A method of fabricating an interconnect structure, comprising:
forming metal lines on a substrate; and
forming a layered dielectric on and between the metal lines, wherein the layered dielectric comprises layers of at least a first dielectric having a first dielectric constant κ₁ and a second dielectric having a second dielectric constant κ₂ deposited in a repeating manner on and between the metal lines, wherein κ₁>κ₂.

17. The method of claim 16, wherein the repeating manner comprises alternating layers of the first dielectric and the second dielectric deposited on and between the metal lines.

18. The method of claim 16, further comprising:
forming the metal lines using a subtractive etching process.

19. The method of claim 16, further comprising:
forming at least one top via that directly contacts one of the metal lines.

20. The method of claim 19, further comprising:
forming the at least one top via using either a subtractive etching process or a damascene process.
